(19) United States
(12) Patent Application Publication
(10) Pub. No.: US 2025/0063841 A1
(43) Pub. Date: Feb. 20, 2025

(54) METHOD FOR DESIGNING METALENS USED FOR IMAGE SENSOR

(71) Applicant: SHENZHEN METALENX TECHNOLOGY CO.,LTD, Shenzhen (CN)

(72) Inventors: Wen JIANG, Shenzhen (CN); Chenglong HAO, Shenzhen (CN); Fengze TAN, Shenzhen (CN); Jian ZHU, Shenzhen (CN)

(73) Assignee: SHENZHEN METALENX TECHNOLOGY CO.,LTD, Shenzhen (CN)

(21) Appl. No.: 18/795,056

(22) Filed: Aug. 5, 2024

(30) Foreign Application Priority Data
Aug. 17, 2023 (CN) 202311044723.7

(51) Int. Cl. H01L 27/146

(52) U.S. Cl. CPC H01L 27/14627; H01L 27/14685

(57) ABSTRACT

A method for designing a metalens used for an image sensor and an image sensor is provided, the method includes: S1. determining a target waveband; S2. according to the target waveband, determining an initial structure parameter and an initial material parameter of the unit cells; S3. optimizing the initial structure parameters of the unit cells and the initial material parameters of the unit cells, so as to obtain target parameters of unit cells; the target parameters of unit cells comprise: a phase of the unit cells and transmittance of the unit cells for an oblique incident light; S4: determining whether the transmittance of the metalens with the target structure parameter of unit cells meets the target transmittance.

### CROSS-REFERENCE TO RELATED APPLICATION

This application claims the benefit of priority from Chinese Patent Application No. 202311044723.7, filed on Aug. 17, 2023. The content of the aforementioned application, including any intervening amendments thereto, is incorporated herein by reference in its entirety.

### TECHNICAL FIELD

The present disclosure relates to the field of an image sensor, in particular to a method for designing a metalens used for an image sensor.

### BACKGROUND

An image sensor is a device for converting optical signals into an electrical signals with an array of pixels. The photosensitive areas and non-photosensitive areas are included on the image sensor, and only the optical signals exposed to the photosensitive area can be converted into electrical signals.

In order to improve the performance of optical detection for the image sensor, the relevant technology integrates a micro-lens or metalens on the photosensitive side of the image sensor to divide the incident light and focus the incident light on the light sensitive area of the image sensor, so as to improve the light energy utilization of the image sensor. However, the images still has the vignetting when the image sensor matches with the optical system in prior art.

Therefore, a new image sensor is urgently needed to suppress the influence of vignetting of the image.

### SUMMARY

In order to solve the technical problem that the images generated by image sensors still have the vignetting, and the image sensors is integrated with metalens. The present disclosure embodiment provides a design method for the image sensor and an image sensor.

In the first aspect, a method for designing a metalens used for an image sensor is provided, and the metalens comprising a substrate and a plurality of unit cells, wherein the method includes:
S1. determining a target waveband;
S2. according to the target waveband, determining an initial structure parameter of the unit cells and an initial material parameter of the unit cells;
S3. optimizing the initial structure parameters of the unit cells and the initial material parameters of the unit cells, so as to obtain a plurality of target parameters of unit cells;
the target parameters of unit cells comprise: a phase of the unit cells and transmittance of the unit cells for an oblique incident light;
S4: determining whether the transmittance of the metalens with the target structure parameter of unit cells meets the target transmittance;
if so, outputting the target parameter of unit cells;
if not, updating the initial structure parameter of the unit cells and the initial material parameter of the unit cells, and repeating the steps from S2 to S4 until the optimized transmittance of the metalens with the target parameter of unit cells meets the target transmittance.

In the second aspect, an image sensor is provided, the image sensor comprises the metalens designed by the method and a photohead sensing device;
the metalens is set on the photosensing side of the photohead sensing device;
the metalens includes the substrate and the unit cells;
the substrate is set on the photosensing side of the photohead sensing device;
the unit cells are set on the side that are away from the photosensing side of the photohead sensing device;
the photohead sensing device includes a plurality of pixel units, and each pixel unit comprises multiple sub-pixels;
each sub-pixel is used to transport optical signals in specific wavelengths into electrical signals.

The above technical scheme provided by the embodiment of the present disclosure achieves at least the following technical effects:

The method for designing a metalens used for an image sensor provided by the disclosure determines an initial structure parameter and an initial material parameter of the unit cells according to the target waveband, so as to obtain a target parameter of unit cells. Then the method optimizes the initial structure parameter and the initial material parameter of the unit cells, so as to obtain the target parameter of unit cells, and the target parameter of unit cells includes: the phases of the unit cells and the transmittance of the unit cells for oblique incident light. In this way, the method improves the photon energy that the photons pass through the metalens and are obliquely incident to the pixels, and compresses the vignetting when matching the image sensor with the optical system.

The image sensor provided by the disclosure is set the metalens on the photosensing side of the photohead sensing device, and the metalens is designed by the above method. In this way, the transmittance of the unit cell for the oblique incident light improves greatly. And the method improves the photon energy that the photons pass through the metalens and are obliquely incident to the pixels, and compresses the vignetting when matching the image sensor with the optical system, and, improves the reception efficiency of the large-angle oblique incident light.

### BRIEF DESCRIPTION OF THE DRAWINGS

The present disclosure may be better understood by reference to the description given below in combination with the drawings, where the same or similar drawing markings are used in all the drawings to represent the same or similar assemblies. The drawings are included in the specification along with the following detailed description and form part of the specification, and to further illustrate the preferred embodiments of the disclosure and explain the principles and advantages of the disclosure.

FIG. 1 shows a flow chart of an optional method for designing a metalens used for an image sensor provided by the embodiment of the present disclosure.

FIG. 2 shows a flow chart of an optional method for designing a metalens used for an image sensor provided by the embodiment of the present disclosure.

FIG. 3 shows a flow chart of an optional method for designing a metalens used for an image sensor provided by the embodiment of the present disclosure.

FIG. 4 a flow chart of an optional method for designing a metalens used for an image sensor provided by the embodiment of the present disclosure.

FIG. 5A shows an optional structural schematic diagram of the image sensor provided by the embodiment of the present disclosure.

FIG. 5B shows an optional structural schematic diagram of the image sensor provided by the embodiment of the present disclosure.

FIG. 5C shows an optional structural schematic diagram of the image sensor provided by the embodiment of the present disclosure.

FIG. 5D shows an optional structural schematic diagram of the image sensor provided by the embodiment of the present disclosure.

FIG. 6A shows a schematic diagram of an optional partial structure of a metalens provided in one embodiment.

FIG. 6B shows a schematic diagram of an optional partial structure of a metalens provided in one embodiment.

FIG. 7 shows a schematic diagram of an optional partial structure of a metalens provided in one embodiment.

FIG. 8 shows a schematic diagram of the transmittance with angle variation of a single-layer metalens.

FIG. 9 shows a schematic diagram of the transmittance with angle variation of an optional metalens.

FIG. 10 shows a schematic diagram of the transmittance with angle variation of another single-layer metalens.

FIG. 11 shows a schematic diagram of the transmittance with angle variation of another double-layer metalens.

### DETAILED DESCRIPTION OF DISCLOSED EMBODIMENTS

The present disclosure is described more comprehensively with reference to the drawings, and embodiments are shown in the drawings. However, the present disclosure may be implemented in many different ways, and should not be interpreted as limited to the embodiment described herein. Instead, these embodiments are provided such that the disclosure will be exhaustive and complete, and will fully convey the scope of the disclosure to those skilled in the art. The same attached drawing marks throughout indicate the same components. Furthermore, in the drawings, the thickness, ratio and size of the components are enlarged to clearly illustrate.

The term used herein is used only for the purpose of describing the specific embodiment and is not intended to be a limitation. The “a”, “an”, “this” and “one” do not represent a limit on the quantity in the disclosure. It is intended to include both singular and plural. For example, “one part” has the same meaning as “at least one part” unless the context clearly indicates otherwise. “At least one” should not be interpreted as limiting to the quantity “one”. “Or” means “and/or”. The term “and/or” includes any and all combinations of one or more of the associated listed items.

Unless the disclosure is limited, all terms used herein, including technical and scientific terms, have the same meaning as commonly understood by those skilled in the field. The terms defined in a jointly used dictionary shall be construed to have the same meaning as those in the relevant technical context and are not interpreted in an idealized or overly formal meaning unless expressly defined in the specification.

The meaning of “include” or “contain” specifies the nature, quantity, step, operation, parts, parts, or combinations thereof, but does not exclude other nature, quantity, step, operation, parts, or a combination of them.

This disclosure describes the implementation with reference to the section diagram as an idealized embodiment. Thus, relative to illustrated shape changes as a result of, for example, manufacturing technique and/or tolerance. Therefore, the embodiments described herein should not be interpreted to be limited to specific shapes of the region as shown herein, but should include deviations from shapes due to fabrication. For example, regions shown or described as flat may typically have coarse and/or non-linear characteristics. Also, the sharp angles shown can be rounded. Thus, the regions shown in the drawings are schematic in nature and their shapes are not intended to show the precise shape of the area and are not intended to limit the scope of the claim.

Embodiments according to the present disclosure will be described below with reference to the accompanying drawings.

The optical device collects optical signals by the optical system (such as a camera lens) and converts the optical signals to the electronic signals. Usually, the CRA (Chief Ray Angle) of the optical system need to be matched with he CRA of the image sensor to compress the vignetting and the aberration of imaging. CRA of the optical system is defined as the maximum angle of light that can be focused on the pixel, where the pixel responsivity at the CRA decreases to 80% of the pixel responsivity at 0°. CRA of the image sensor is defined as the maximum light angle that can be corrected when ensuring the center of the efficiency of photosensitive pixel of the photo-diode pixel is 80%.

The image sensor integrated with micro-lens or metalens in the prior art still has a problem of significantly low detection efficiency. For example, the image sensors in the prior art integrated with the metalens can divide and focus the incident light by the metalens, but the detection efficiency decreases significantly when the detection angle is greater than 17°.

The applicants of the present application unexpectedly found that the limitations of light energy utilization for the detector can be reduced by using the metalens to divide the light, especially will increase the intensity of the vertical incident light signal. However, when the light is incident obliquely at a larger angle, the photon energy of the incident pixel is insufficient, which leads to the insufficient vignetting or illumination, and the receiving efficiency of the oblique-incident light at a larger angle decreases significantly.

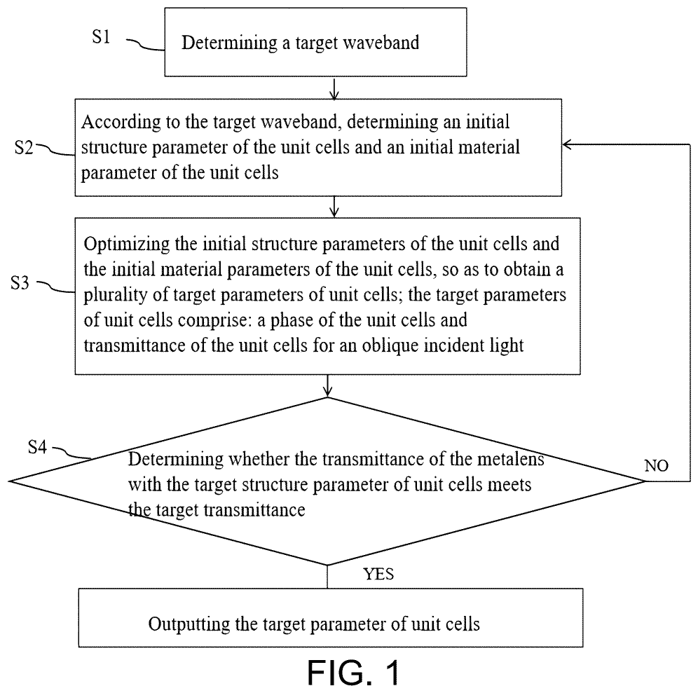

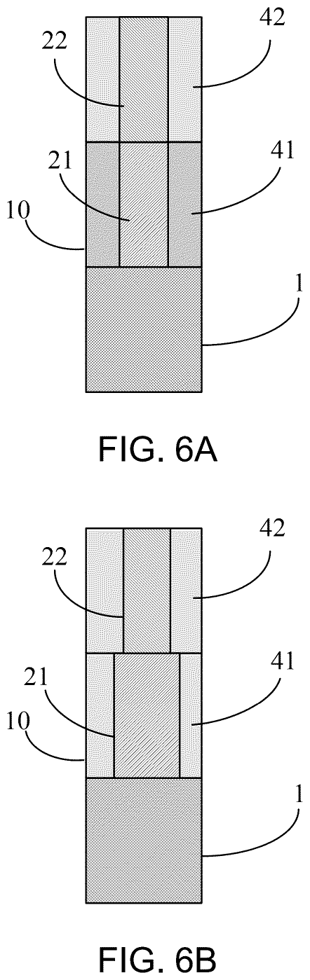

For the above reasons, in the first aspect, a method for designing a metalens used for an image sensor is provided by the present disclosure. As shown in FIG. 6A, the metalens includes a unit cell 10 and a substrate 1. As shown in FIG. 1, the method at least includes the following S1-S4.

S1. determining a target waveband. The target waveband is determined by the design requirement of the working waveband for the image sensor, such as a visible light band, a near infrared band, a medium infrared band or a far infrared band.

S2. according to the target waveband, determining an initial structure parameter of the unit cells and an initial material parameter of the unit cells. A number of layers of the unit cells is greater than or equal to 2, and each layer of the unit cells includes a nanostructure; the initial structure parameter includes the number of layers of the unit cells, a type, shape, characteristics dimension, and periodicity of the nanostructures in each layer of unit cells; the initial material parameter of the unit cells includes the refractive index of the nanostructure.

Optionally, the type of the nanostructure includes a positive nanostructure or a negative nanostructure. The positive nanostructure protrudes on the surface of the substrate. The negative nanostructure extends from the surface of the substrate to the opposite surface of the surface. Optionally, the shape of the nanostructure includes at least one or more combinations of a cylinder, round platform, cone, pyramid, prism, edge platform, annular column, and semi-annular column. Optionally, the characteristic dimensions of the nanostructures include the height of the nanostructures, the outer circle diameter of the cross-section perpendicular to the height axis, and the aspect ratio of the nanostructure, etc. In the following, the outer circle diameter of the cross-section perpendicular to the height axis will be referred to as the diameter of the nanostructures. It should be noted that the height, diameter, refractive index of the nanostructures and the refractive index of the filler material will all influence the transmittance of the metalens.

In some optional embodiments, each layer of the unit cells also includes a filler material, and the filler material is used to fill the gaps between the adjacent nanostructures, and the initial material parameter of the unit cells comprises the refractive index of the filler material. Optionally, the absolute value of the difference between the refractive index of the filler material and the refractive index of the nanostructures is greater than or equal to 0.5. Optionally, the filler material may be air.

In some optional embodiments, the metalens further includes: a buffer layer, and the buffer layer is at least set on one side of each layer of the unit cells; the initial structure parameter includes the thickness of the buffer layer and the refractive index of the buffer layer.

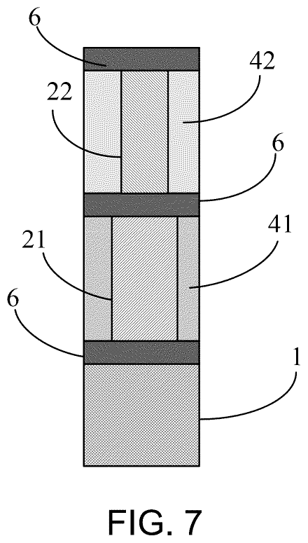

As shown in FIG. 7, the buffer layer 6 may optionally be set between the adjacent layers of unit cells, between the lowest layer of the unit cells and the substrate, and at the top of the topmost layer of the unit cells.

S3. optimizing the initial structure parameter of the unit cells and the initial material parameter of the unit cells, so as to obtain a plurality of target parameters of unit cells. The target parameter of unit cells includes: a phase of the unit cells and transmittance of the unit cells for an oblique incident light. It should be noted that the transmittance of the unit cells for oblique incident light refers to the transmittance of the unit cells as incident light obliquely passes through the unit cells. According to the embodiment of the present disclosure, the phases of the unit cell is capable of covering phases from 0 to 2π. Based on the phase modulation principle of the metalens, if the phase variations of the unit cells cannot cover phases from 0 to 2π, it cannot effectively control the propagation direction of the light wave, so that the unit cells cannot realize the optical function.

In an optional embodiment, the transmittance of the unit cell for oblique incident light is greater than or equal to the target transmittance. And the term of “obliquely incident” means the incident angle of light is greater than 0″. The target transmittance is determined by the design requirement of the image sensor. The obliquely incident light passes through the metalens and illuminates the photosensitive area of the image sensor. Therefore, increasing the transmittance of the unit cell for oblique incident light can increase the photon energy of the oblique incident light to the photosensitive area. In some optional embodiment, the method includes: optimizing transmittance of the unit cell for the oblique incident light and a vertically incident transmittance at the same time. In some optional embodiment, the method includes: only optimizing transmittance of the unit cell for the oblique incident light. In some optional embodiment, the method includes: determining whether the minimum value of the transmittance of the unit cell for the oblique incident lights is greater than or equal to the target transmittance. In some optional embodiment, the method includes: determining whether the transmittance with a reference angle of the unit cells is greater than or equal to the target transmittance. In some optional embodiment, the method includes: determining whether the transmittance with a reference angle of the unit cells is greater than or equal to the target transmittance. The reference angle is determined by the design requirement of the image sensor. For example, the reference angle is determined by the distance between the adjacent pixels.

Optionally, the target transmittance is greater than or equal to 60%. Optionally, the target transmittance is greater than or equal to 65%. Optionally, the target transmittance is greater than or equal to 70%. Optionally, the target transmittance is greater than or equal to 75%. Optionally, the target transmittance is greater than or equal to 80%. Optionally, the target transmittance is greater than or equal to 85%. Optionally, the target transmittance is greater than or equal to 90%.

According to the embodiment of the present disclosure, “optimizing the initial structure parameter of the unit cells and the initial material parameter of the unit cells” may be a direct optimization method. The direct optimization method refers to search for the globally optimal or locally optimal structure parameters of the unit cells in the range that metalens fabrication allows by finding the optimal solution algorithm. The aforementioned optimal solution algorithm includes a gradient descent algorithm, inner point method, genetic algorithm, Newton method, simulated annealing algorithm, etc. According to the embodiment of the present disclosure, the optimization method of “optimizing the initial structure parameter of the unit cells and the initial material parameter of the unit cells” may also be to obtain a global optimum or a local optimum by performing an ergodic approach on all the parameters.

S4. determining whether the transmittance of the metalens with the target structure parameter of unit cells meets the target transmittance; if so, outputting the target parameter of unit cells; if not, updating the initial structure parameter of the unit cells and the initial material parameter of the unit cells, and repeating the steps from S2 to S4 until the optimized transmittance of the metalens with the target parameter of unit cells meets the target transmittance.

According to the embodiment of the present disclosure, the target parameter of unit cells may be directly used to process metalens. Because there are fewer nanostructures that simultaneously satisfy the phase covering from 0 to 2π and the transmittance of the unit cells for the oblique incident light is greater than or equal to the target transmittance, the method may increase the design freedom of the nanostructures, to obtain more structures that can meet the aforementioned optimization target simultaneously. For example, the number of layers in the initial structure parameters and the combination of structure type, characteristic dimensions, or periodicity of the nanostructure in any layer may be re-input. For example, the new material parameters may also be re-input.

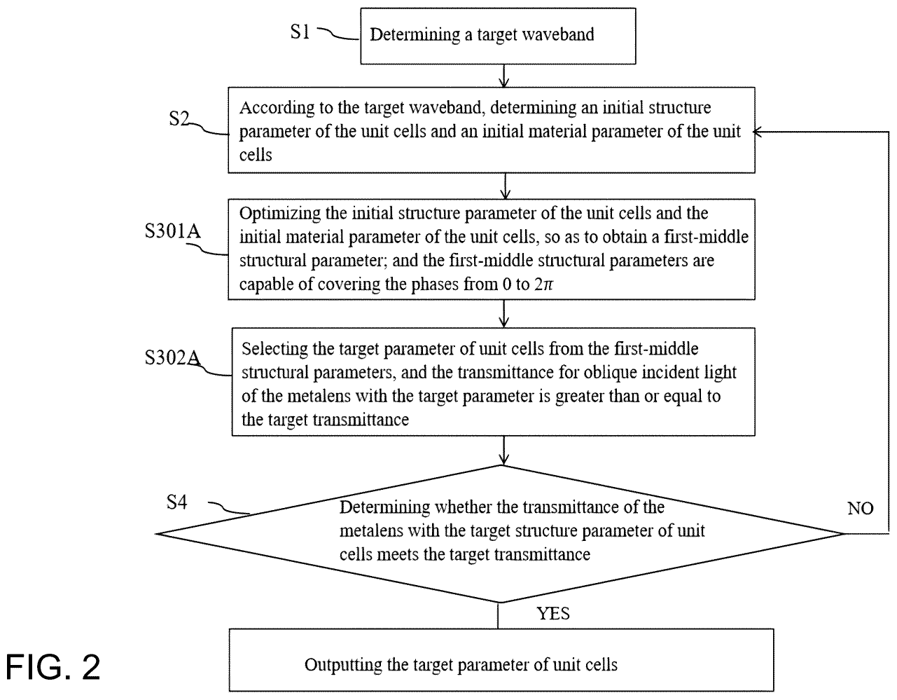

More specifically, FIGS. 2, 3, and 4 respectively show optional optimization paths for the design method of the metalens provided by the embodiment of the present disclosure.

In some optional embodiments, as shown in FIG. 2, S3 specifically includes:

S301A. optimizing the initial structure parameter of the unit cells and the initial material parameter of the unit cells, so as to obtain a first-middle structural parameter; and the first-middle structural parameter is capable of covering the phases from 0 to 2;

S302A. selecting the target parameter of unit cells from the first-middle structural parameter, and the transmittance for oblique incident light of the metalens with the target parameter is greater than or equal to the target transmittance.

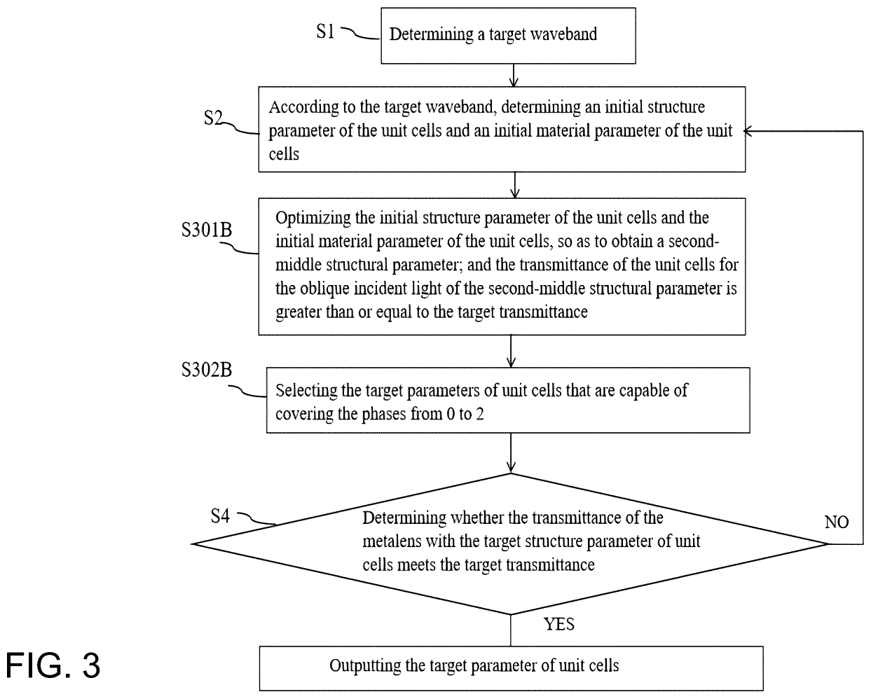

In some optional embodiments, as shown in FIG. 3, S3 specifically includes:

S301B. optimizing the initial structure parameter of the unit cells and the initial material parameter of the unit cells, so as to obtain a second-middle structural parameter; and the transmittance for oblique incident light of the second-middle structural parameter is greater than or equal to the target transmittance.

S302B. selecting the target parameter of unit cells that is capable of covering the phases from 0 to 2π.

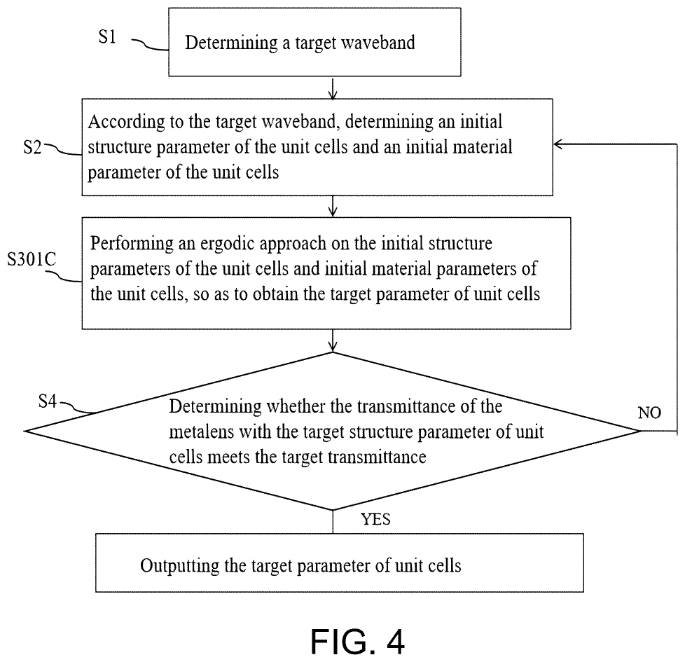

In some optional embodiments, as shown in FIG. 4, S3 specifically includes:

S301C. performing an ergodic approach on the initial structure parameter of the unit cells and initial material parameter of the unit cells, so as to obtain the target parameter of unit cells.

According to the embodiment of the present disclosure, in S3, the diameter and height of the nanostructure in each layer of the unit cells are selected as variables. The variations range of the diameter of the nanostructures is limited by the minimum line-width fabrication. The periodicity of the nanostructure is about half of the minimum wavelength in the target waveband. The height of the nanostructure may satisfy the phases of covering from 0-21. The target waveband as the visible light is taken for an example, usually, the line-width fabrication of the nanostructures used for the visible light band is about 50 nm. If the target waveband is the infrared band, the line-width fabrication is about 500 nm, and the periodicity of the nanostructure is about 2 to 3 μm.

### Embodiment 1

Embodiment 1 illustrates an optimization result for optimizing a metalens (single-layer metalens) with the single-layer unit cells according to the method provided in the embodiment of the present disclosure. In embodiment 1, firstly the target waveband is determined to be visible light, and the wavelengths of 430 nm, 550 nm, and 670 nm are selected to be the analyzed wavelengths for detecting the optimized transmittance of the metalens. And the phases of covering from 0 to 2π and the transmittance of the unit cells for the oblique incident light from 16°-30° are taken to be the optimized target.

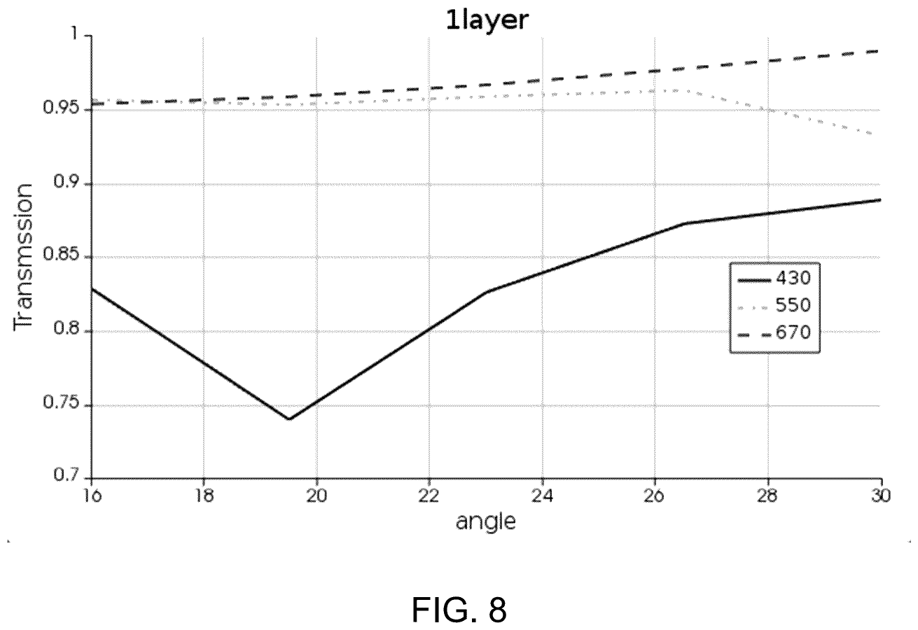

FIG. 8 shows the schematic diagram of the transmittance with angle variation of the incident light for a single-layer metalens. The nanostructure of the single-layer metalens is a cylindrical positive structure, and the material is alumina, and the filler material between the nanostructures is silica. The nanostructures are arranged in a periodicity of 300 nm to 400 nm, a height of 700 nm to 800 nm and a diameter of 200 nm. As shown in FIG. 8, the transmittance of a single-layer metalens at the wavelength of 430 nm is smaller than 75% when the incidence angles are at from 16 to 30°.

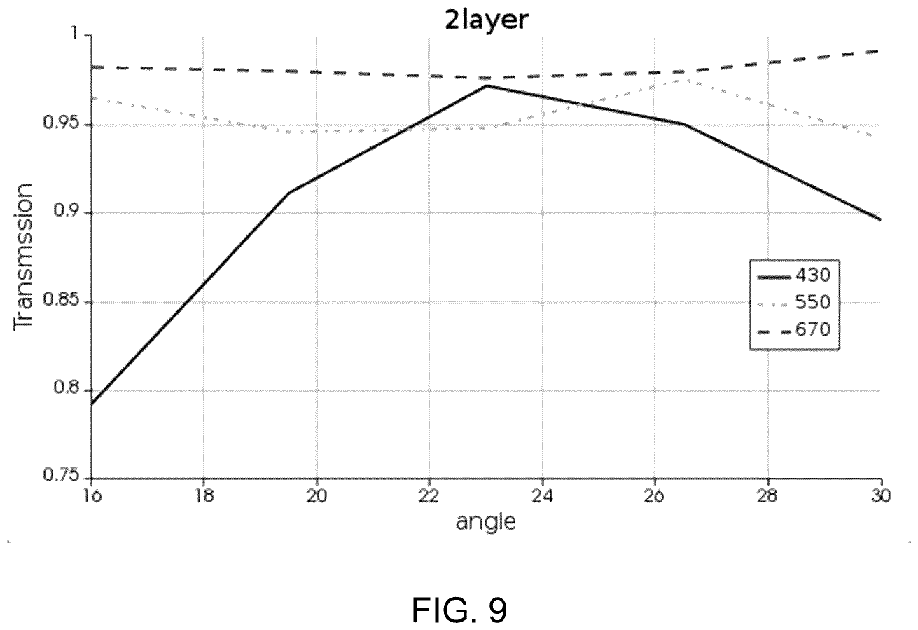

FIG. 9 shows a schematic diagram of the transmittance with angle variation of optional metalens (double-layer metalens). The nanostructures in the double-layer metalens all are cylindrical positive nanostructures. Moreover, in the double-layer unit cells, the layer of unit cells near the substrate includes the first nanostructures and the first filler material filled between the gaps between the first nanostructures. The first nanostructures are made of alumina, and the first filler material is silica. The unit cells far away from the substrate include the second nanostructures and a second filler material filled between the gap of the second nanostructures. The second nanostructures are made of silicon nitride and the second filler material of silica. The first nanostructures have a periodicity of 300 nm to 400 nm, a height of 900 nm to 1100 nm and a diameter of 200 nm. As shown in FIG. 9, the transmittance of the double-layer metalens at the wavelength of 430 nm is greater than 85% when the incident angle is from 18° to 20°. As shown in FIG. 9, the average transmittance of the optimized single-layer metalens for the three analyzed wavelengths increased from 91% to 95%.

### Embodiment 2

Embodiment 2 illustrates an optimization result for optimizing a metalens (double-layer metalens) with a two-layer unit cell according to the method provided in the embodiment of the present disclosure. In embodiment 2, firstly the target waveband is determined to be visible light, and the wavelengths of 430 nm, 550 nm, and 670 nm are selected to be the analyzed wavelength for detecting the optimized transmittance of the metalens. And the phase of covering 2π and the for the transmittance of unit cells for oblique incident light from 16° to 30° are taken to be the optimized target.

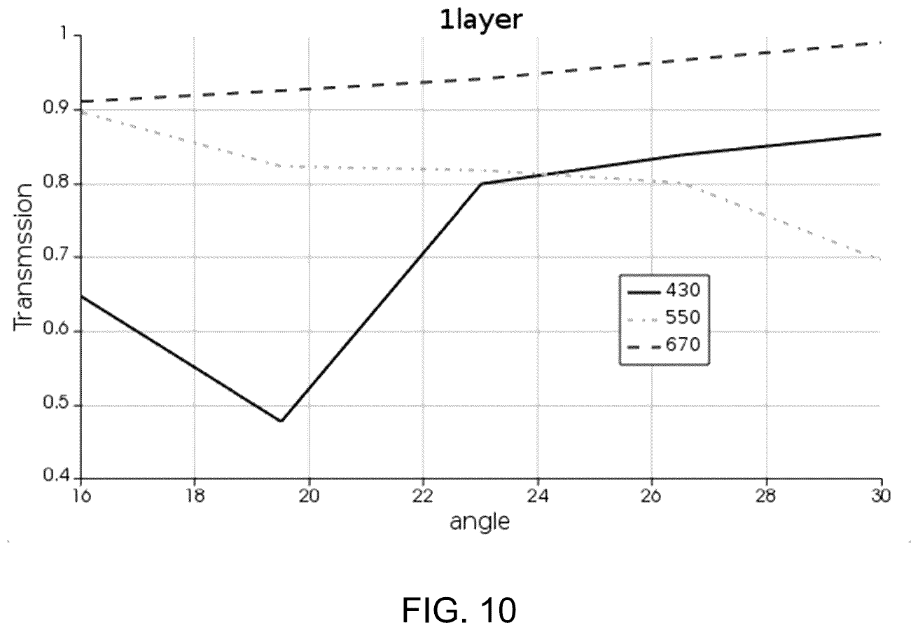

FIG. 10 shows a schematic diagram of the transmittance with angle variation of an optional metalens (single-layer metalens). The nanostructures in the single-layer metalens all are cylindrical positive nanostructures. And the material of the nanostructures is silicon nitride, and the filler material between the nanostructures is silicon dioxide. The nanostructure has a periodicity of 300 nm to 400 nm, a height of 900 nm to 1100 nm and a diameter of 200 nm. As shown in FIG. 8, the transmittance of the single-layer metalens is smaller than 90% at the wavelengths of 430 nm and 550 nm when the obliquely incident angles are from 16°-30°.

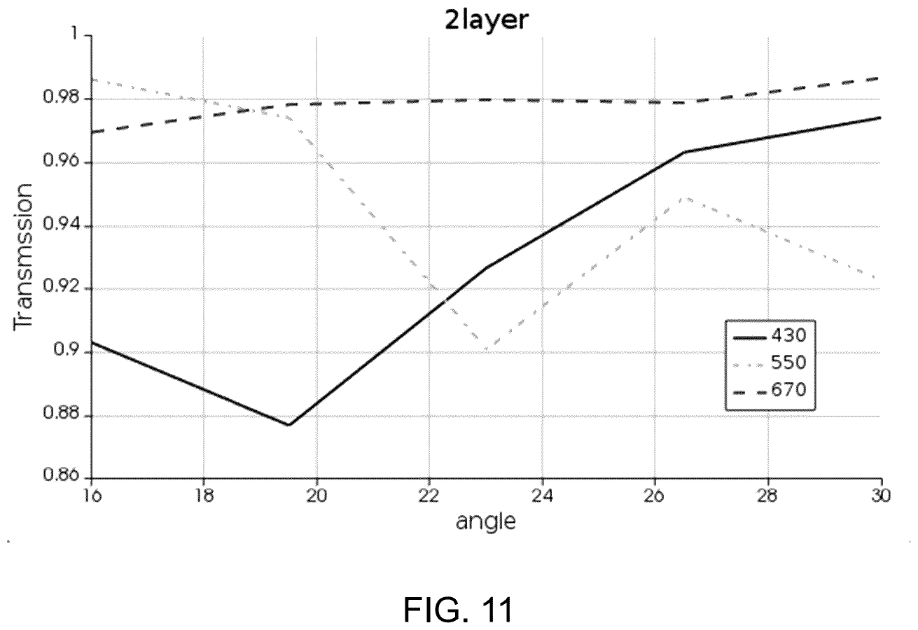

FIG. 11 shows a schematic diagram of the optimized transmittance with angle variation of another single-layer metalens. The nanostructures in the double-layer metalens all are cylindrical positive nanostructures. The first nanostructure and the second nanostructure are made of silicon nitride, and the filler material between the first nanostructures and the second filler material between the second nanostructures are silica dioxide. The first nanostructure has a periodicity of 300 nm to 400 nm, a height of 1200 nm to 1400 nm, and a diameter of 160 nm. The second nanostructures have a periodicity of 300 nm to 400 nm, a height of 400 nm to 550 nm, and a diameter of 200 nm. As shown in FIG. 11, the transmittance of the double-layer metalens is greater than or equal to 90% when the incident angle is at 16°-30°. As shown in FIG. 11, when the incident angle is from 16°-30°, the average transmittance of the optimized double-layer metalens for the three analyzed wavelengths increased from 83% to 95%.

The method for designing a metalens used for an image sensor provided by the disclosure determines an initial structure parameter and an initial material parameter of the unit cells according to the target waveband, so as to obtain a target parameter of unit cells. Then the method optimizes the initial structure parameter and the initial material parameter of the unit cells, so as to obtain the target parameter of unit cells, and the target parameter of unit cells includes: the phase of the unit cells and the transmittance of the unit cells for oblique incident light. In this way, the method improves the photon energy that the photons pass through the metalens and are obliquely incident to the pixels, and compresses the vignetting when matching the image sensor with the optical system.

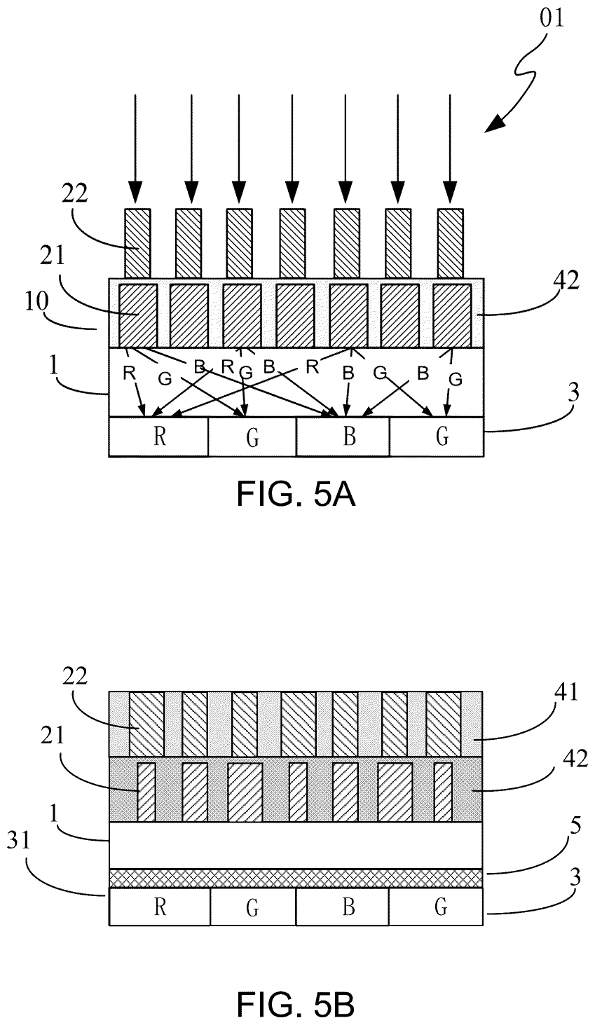

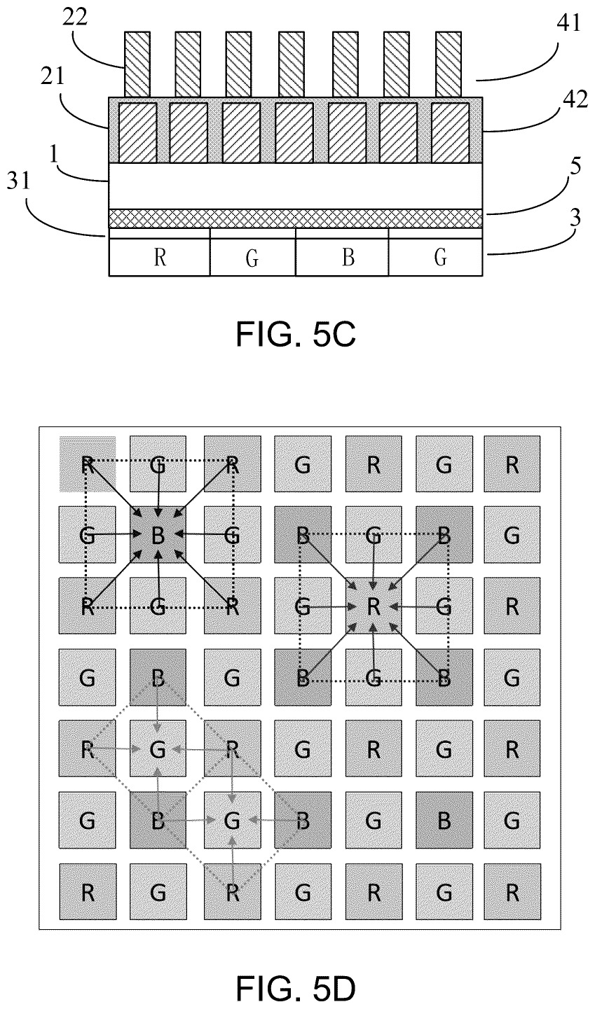

For another aspect, as shown from FIG. 5A to FIG. 7, an image sensor is provided. The image sensor includes the metalens designed by any above embodiment and a photohead sensing device 3.

Specifically, as shown in FIG. 5A, the metalens includes the substrate and the unit cells; the unit cells are set on the side that is away from the photosensing side of the photohead sensing device; the photohead sensing device includes a plurality of pixel units, and each pixel unit includes multiple sub-pixels; each sub-pixel is used to convert optical signals in specific bands into electrical signals.

The metalens includes a plurality of unit cells, and each unit cell and each pixel unit correspond one to one; each unit cell is used to modulate the phase of the incident light, so the light with different wavebands transmits to the sub-pixel in the corresponding pixel unit; the wavelength transmits the incident light and the working waveband of the corresponding sub-pixel As shown in FIG. 5A, the incident light 01 is incident from air to the metalens, and passes through the second nanostructure 22 and the first nanostructure 21, sequentially. After being modulated by the second nanostructure 22 and the first nanostructure 21, the incident light 01 outgoes from the metalens. After being modulated by the metalens, the incident light is emitted into the sub-pixels matching the different waveband in the photoelectric sensing device 3.

The target waveband of the image sensor includes a visible light band; each pixel unit includes four sub-pixels, and the four sub-pixels are red sub-pixel, green sub-pixel, green sub-pixel, and blue sub-pixel, respectively; each unit cell is configured to transmit the lights of the red waveband, the green waveband, and the blue waveband to the red sub-pixel, the green sub-pixel, the green sub-pixel, and the blue sub-pixel, respectively.

FIG. 5D shows a top view of the sub-pixel array of the image sensor. As shown in FIG. 5D, the red sub-pixel (R), green sub-pixel (G), and blue sub-pixel (B) are arranged. After the incident light is modulated by the metalens, the lights of red waveband are transmitted to the red sub-pixel (R), the lights of green waveband are transmitted to the green sub-pixel (G), and the lights of blue waveband are transmitted to the blue sub-pixel (B).

According to the embodiment of the present disclosure, the unit cells 10 have at least two layers. The unit cells in each layer includes a plurality of nanostructures. For example, the metalenses shown in FIGS. 6A and 6B include two-layer unit cells 10, the two-layer unit cells near the substrate includes a first nanostructure 21, and the unit cells away from the substrate includes a second nanostructure 22. The first nanostructure 21 is provided on the side of the substrate 1 far away from the photoelectric sensing device 3, and the second nanostructure 22 is provided on the side of the first nanostructure 21 far away from the substrate 1.

In one embodiment, the structural parameters of the nanostructures in the same layer of the unit cells may be the same. As shown in FIG. 5A, the first nanostructure 21 has the same structural parameters, and the second nanostructure 22 has the same structural parameters. In another embodiment, the structure parameters of the nanostructures in the same layer of the unit cells may be different, as shown in FIG. 5B, the structural parameters (e. g., diameter) of the layers are different, and the structural parameters (e. g., diameter) of the layers are completely different or only partially the same to each other.

In an optional embodiment, the nanostructure are in a coaxial arrangement in any adjacent two layers of unit cells 10. As shown in FIG. 6B, the first nanostructure 21 and the second nanostructure 22 are located in longitudinally adjacent two layers of unit cells, respectively. And the longitudinal central axis of the first nanostructure 21 and the longitudinal central axis of the second nanostructure 22 are dashed lines as shown in FIG. 6B, That is to say, the first nanostructure 21 and the second nanostructure 22 are in a coaxial arrangement.

In other optional embodiment, the nanostructures in any adjacent two layers of unit cells are configured with different axes, that is, the longitudinal central axis of the first nanostructure 21 and the longitudinal central axis of the second nanostructure 22 are not collinear.

According to the embodiment of the present disclosure, the structure parameters of the nanostructures in any two layers of unit cells 10 are the same. Optionally, as shown in FIG. 6A, the first nanostructure 21 has the same structural parameters as the second nanostructure 22, such as height, shape, characteristic dimension, periodicity, etc., but the material of the first nanostructure 21 in FIG. 6A is different from the second nanostructure 22.

According to the embodiment of the present disclosure, the structure parameters of the nanostructures in any two layers of the unit cells 10 are different. For example, the diameter of the first nanostructure 21 is different from the second nanostructure 22. As shown in FIG. 6B, the diameter of the first nanostructure 21 is greater than the diameter of the second nanostructure 22. In another embodiment, the diameter of the first nanostructure 21 may be smaller than the diameter of the second nanostructure 22.

According to the embodiment of the present disclosure, the structure parameters of the nanostructures in any adjacent two layers of the unit cells are at least partially different. As shown in FIGS. 5A to 5C, the structure parameters of the first nanostructures 21 differ from the second nanostructures 22, such as at least one of the type, height, shape, characteristic dimension, and periodicity. The shadows of the first nanostructures 21 and the second nanostructures 22 are different from FIGS. 5A to 5C, which means the difference of the material of the first nanostructures 21 and the second nanostructures 22. According to the embodiment of the present disclosure, the material of the first nanostructures 21 and the second nanostructures 22 may be the same.

According to the embodiment of the present disclosure, the material of the nanostructure in any two of the unit cells may be same or different. If the materials and structural parameters of the nanostructures in any two adjacent unit cells are the same, it is equivalent to a single-layer metalens composed of height increased single-layer unit cells.

According to the embodiment of the present disclosure, the material of substrate 1 includes one or more combinations of amorphous silicon, compound semiconductor, silicon carbide, alumina, titanium dioxide, silicon dioxide, and silicon nitride. The materials of nanostructure 2 include one or more combinations of amorphous silicon, compound semiconductor, silicon carbide, alumina, titanium dioxide, silicon dioxide, and silicon nitride. Optionally, the material of the substrate 1 and the nanostructure 2 in the unit cell 10 may be the same. Optionally, the substrate 1 and the nanostructure 2 may be made of different materials. Optionally, the substrate 1 and nanostructure 2 may be the same material.

In some embodiments, the gap between the nanostructure 2 is also filled with the filler material 4. Optionally, the absolute value of the difference between the refractive index of the filler material 4 and the refractive index of the nanostructure is greater than or equal to 0.5. According to the embodiment of the present disclosure, the material of the filler material 4 includes one or more combinations of amorphous silicon, compound semiconductor, silicon carbide, alumina, titanium dioxide, silicon dioxide, and silicon nitride, photoresist (e. g. SU-8), and polymers (e. g. PMMA, Polymethyl methacrylate, also known as acrylic). Optionally, the filler materials in any two-layer of the adjacent unit cells may be the same (as shown in FIG. 6B) or different (as shown in FIG. 6A). Optionally, as shown in FIG. 5A, the filler material in the uppermost unit cells may be air.

In some embodiments, the height of the filler material may be different from the height of the unit cell. The filler material in the unit cell near the substrate is higher than the nanostructure. In other embodiments, the height of the filler material can be the same as the height of the nanostructure, and the filler material in the unit cell far away from the substrate in FIG. 5A is the same height, which may be smoothed to the same height of the nanostructure by CMP (chemical-mechanical planarization) technology.

According to the embodiment of the present disclosure, the metalens also includes a buffer layer. The buffer layer is located on at least one side of any layer of unit cells. The thickness, refractive index, and the number of layer of the buffer layer will influence the transmittance of the metalens. Typically, as shown in FIG. 7, a buffer layer 6 is provided between the lowest layer unit cell and the substrate 1, between the two adjacent layer of the unit cell, and at the top of the highest layer of the unit cell. Optionally, the thickness of each buffer layer can be the same or different. Optionally, the refractive index of each buffer layer can be the same or different.

Optionally, as shown in FIG. 5B, the image sensor further includes a glue layer, and the substrate and the filter is connected by the glue layer.

The photohead sensing device includes a plurality of pixel units arranged in an array.

Optionally, as shown in FIG. 5B, a filter is set on the upstream of the optical path of each sub-pixel, and the filter allows specific wavelengths of light to pass through. For example, a filter set on the upstream of the optical path of the red sub-pixel is configured to allow the light of red waveband to pass through, a filter set on the upstream of the optical path of the green sub-pixel is configured to allow the light of green waveband to pass through, and a filter set one the upstream of the optical path of the blue sub-pixel is configured to allow the lights of blue waveband to pass through. The filter 31 covers on the photosensitive side of the photohead sensing device. In one embodiment, the filter 31 may be a Bayer filter. According to the embodiment of the present disclosure, the photohead sensing device 3 may not have a filter 31, and focus the light at different wavelengths to the corresponding pixel only by the modulation of the metalens. For example, when the photohead sensing device 3 includes the filter 31, the substrate 1 is connected to the filter 31 through the glue layer 5, thus realizing the integration of the metalens and the photohead sensing device. According to the embodiment of the present disclosure, the glue layer 5 includes UV curing adhesive and hot curing adhesive.

It should be noted that the metalens provided by the embodiment of the present disclosure can be processed through a semiconductor fabrication and has the advantages of light weight, thin thickness, simple structure and process, low cost and high consistency in mass production.

The method for designing a metalens used for an image sensor provided by the disclosure determines an initial structure parameter and an initial material parameter of the unit cell according to the target waveband, so as to obtain a target parameter of unit cells. Then the method optimizes the initial structure parameter and the initial material parameter of the unit cell, so as to obtain the target parameter of unit cells, and the target parameter of unit cells includes: a phase of the unit cell and an transmittance of the unit cell for oblique incident light. In this way, the method improves the optical energy that the light passes through the metalens and is obliquely incident to the pixels, and compresses the vignetting when matching the image sensor with the optical system.

The image sensor provided by the disclosure is set the metalens on the photosensing side of the photohead sensing device, and the metalens is designed by the above method. In this way, transmittance for oblique incident light from improves greatly. And the method improves the photon energy that the photons pass through the metalens and is obliquely incident to the pixels, and compresses the vignetting when matching the image sensor with the optical system, and, improves the reception efficiency of the large-angle oblique incident light.

The above is only a specific embodiment of the embodiments of this disclosure, but the scope of protection of the embodiment of this disclosure is not limited to this. And those skilled in the field can easily think of any change or substitution for this disclosure, which should be covered within the protection scope of this disclosure. Therefore, the scope of the protection of the present disclosure shall be the scope of the claims.

What is claimed is:

1. A method for designing a metalens used for an image sensor, and the metalens comprising a substrate and a plurality of unit cells, wherein the method comprises:
S1: determining a target waveband;
S2: according to the target waveband, determining an initial structure parameter of the unit cells and an initial material parameter of the unit cells;
S3: optimizing the initial structure parameters of the unit cells and the initial material parameters of the unit cells, so as to obtain a plurality of target parameters of unit cells;
the target parameters of unit cells comprise: a phase of the unit cells and transmittance of the unit cells for an oblique incident light;
S4: determining whether the transmittance of the metalens with the target structure parameter of unit cells meets the target transmittance;
if so, outputting the target parameter of unit cells;
if not, updating the initial structure parameter of the unit cells and the initial material parameter of the unit cells, and repeating the steps from S2 to S4 until the optimized transmittance of the metalens with the target parameter of unit cells meets the target transmittance.

2. The method according to claim 1, wherein the S3 further comprises:
optimizing the transmittance of the unit cells for oblique incident light and a transmittance of the unit cells for vertical incident light at the same time.

3. The method according to claim 1, wherein the S3 comprises:
S301A: optimizing the initial structure parameter of the unit cells and the initial material parameter of the unit cells, so as to obtain a first-middle structural parameter; and the first-middle structural parameters are capable of covering the phases from 0 to 2π;
S302A: selecting the target parameter of unit cells from the first-middle structural parameters, and the transmittance for oblique incident light of the metalens with the target parameter is greater than or equal to the target transmittance.

4. The method according to claim 1, wherein S3 comprises:
S301B: optimizing the initial structure parameter of the unit cells and the initial material parameter of the unit cells, so as to obtain a second-middle structural parameter;
and the transmittance of the unit cells for the oblique incident light of the second-middle structural parameter is greater than or equal to the target transmittance;
S302B: selecting the target parameters of unit cells that are capable of covering the phases from 0 to 2π.

5. The method according to claim 1, wherein S3 comprises:
S301C: performing an ergodic approach on the initial structure parameters of the unit cells and initial material parameters of the unit cells, so as to obtain the target parameter of unit cells.

6. The method according to claim 1, wherein a number of layers of the unit cells is greater than or equal to 2, and each layer of the unit cell comprises a nanostructure;
the initial structure parameters of the unit cells comprise the number of layers of the unit cells, a type, shape, characteristics dimension, and periodicity of the nanostructures in each layer of unit cells;
the initial material parameters of the unit cells comprise the refractive index of the nanostructures.

7. The method according to claim 6, wherein each layer of the unit cells further comprises a filler material, and the filler material is used to fill the gaps between the adjacent nanostructures, and the initial material parameters of the unit cells comprise the refractive index of the filler material.

8. The method according to claim 6, wherein the metalens further comprises: a buffer layer, and the buffer layer is at least set on one side of each layer of the unit cells;
the initial structure parameters comprise the thickness of the buffer layer and the refractive index of the buffer layer.

9. An image sensor, wherein the image sensor comprises the metalens designed by the method of claim 1 and a photohead sensing device;
wherein, the metalens is set on the photosensing side of the photohead sensing device;
the metalens comprises the substrate and the unit cells;
the substrate is set on the photosensing side of the photohead sensing device;
the unit cell is set on the side that is away from the photosensing side of the photohead sensing device;
the photohead sensing device comprises a plurality of pixel units, and each pixel unit comprises multiple sub-pixels;
each sub-pixel is used to convert optical signals in specific bands into electrical signals.

10. The image sensor according to claim 9, wherein the metalens comprises a plurality of unit cells, and each unit cell and each pixel unit correspond one to one;
each unit cell is used to modulate the phase of the incident light, so the light with different wavebands transmits to the sub-pixel in the corresponding pixel unit;
the wavelength transmitted incident light and the working waveband of the sub-pixel correspond.

11. The image sensor according to claim 9, wherein a filter is set on the upstream of the optical path of each sub-pixel, and the filter allows specific wavelengths of light to pass through.

12. The image sensor according to claim 11, wherein the image sensor further comprises a glue layer, and the substrate and the filter is connected by the glue layer.

13. The image sensor according to claim 9, wherein the target waveband of the image sensor comprises a visible light band;
each pixel unit comprises four sub-pixels, and the four sub-pixels are red sub-pixel, green sub-pixel, green sub-pixel, and blue sub-pixel, respectively;
each unit cell is configured to transmit the lights of the red waveband, the green waveband, and the blue waveband to the red sub-pixel, the green sub-pixel, the green sub-pixel, and the blue sub-pixel, respectively.

14. The image sensor according to claim 9, wherein the unit cell has at least two layers.

15. The image sensor according to claim 14, wherein when the unit cells are a two-layer structure, the two-layer unit cells near the substrate includes a first nanostructure, and the unit cell away from the substrate includes a second nanostructure.

16. The image sensor according to claim 15, wherein the first nanostructure is set on the side of the substrate far away from the photoelectric sensing device, and the second nanostructure is set on the side of the first nanostructure far away from the substrate.
